(19) United States
(12) Patent Application Publication
(10) Pub. No.: US 2025/0038079 A1
(43) Pub. Date: Jan. 30, 2025

(54) SEMICONDUCTOR DEVICE AND POWER CONVERSION APPARATUS

(71) Applicant: Mitsubishi Electric Corporation, Tokyo (JP)

(72) Inventors: Ren KUGA, Tokyo (JP); Ryo GOTO, Tokyo (JP)

(73) Assignee: Mitsubishi Electric Corporation, Tokyo (JP)

(21) Appl. No.: 18/637,391

(22) Filed: Apr. 16, 2024

(30) Foreign Application Priority Data
Jul. 27, 2023 (JP) 2023-122225

(51) Int. Cl. H01L 23/498; H01L 23/00; H02M 7/00

(52) U.S. Cl. CPC H01L 23/49811; H01L 23/49844; H01L 24/32; H01L 24/48; H01L 24/73; H02M 7/003; H01L 2224/32175; H01L 2224/48; H01L 2224/73265; H01L 2924/1815

(57) ABSTRACT

The technique disclosed in the present specification is a technique for effectively reducing resistance even when the electrode shape has irregularities. A technique disclosed in the present specification is a semiconductor device includes a semiconductor chip, a case that houses the semiconductor chip therein, a main electrode electrically connected to the semiconductor chip via a wire and partially exposed to outside from the case, and a conductive material applied to a front surface of the main electrode exposed from the case, in which the front surface of the main electrode is the surface connected to a bus bar.

### BACKGROUND OF THE INVENTION

### Field of the Invention

The technique disclosed in the present specification relates to semiconductor technique.

### Description of the Background Art

As a method for suppressing contact resistance between a bus bar and a main electrode of a semiconductor device, for example, a method disclosed in Japanese Patent Application Laid-open No. 2006-294849 is known.

However, in the method disclosed in Japanese Patent Application Laid-Open No. 2006-294849, the contact area is small when the main electrode has irregularities on its front surface, leading to an inability to reduce contact resistance or contact thermal resistance in many cases.

### SUMMARY

The technique disclosed in the present specification is a technique for effectively reducing resistance even when the electrode shape has irregularities.

A first aspect of a technique disclosed in the present specification is a semiconductor device includes a semiconductor chip, a case that houses the semiconductor chip therein, a main electrode electrically connected to the semiconductor chip via a wire and partially exposed to outside from the case, and a conductive material applied to a front surface of the main electrode exposed from the case, in which the front surface of the main electrode is the surface connected to a bus bar.

According to the at least first aspect of the technique disclosed in the present specification, the main electrode contacts the bus bar through the conductive material, so even if the main electrode or the bus bar has irregularities, the contact area between the main electrode and the bus bar does not reduce, thereby reducing the contact resistance or contact thermal resistance. The contact resistance or contact thermal resistance between the main electrode and the bus bar.

The objects, characteristics, aspects, and advantages of the technique disclosed in the present specification will become more apparent from the following detailed description and the accompanying drawings.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram illustrating an example of a configuration of a semiconductor device according to Embodiment;

FIG. 2 is a cross-sectional view illustrating an example taken along line A-A′ in FIG. 1;

FIG. 3 is a diagram illustrating an example of a configuration when a bus bar is externally connected to the main electrode;

FIG. 4 is a cross-sectional view illustrating the example of the configuration when the bus bar is connected to the main electrode illustrated in FIG. 3;

FIG. 5 is a diagram illustrating an example of a configuration when the bus bar is externally connected to the main electrode of the semiconductor device according to Embodiment;

FIG. 6 is a cross-sectional view illustrating the example of the configuration when the bus bar is connected to the main electrode illustrated in FIG. 5;

FIG. 7 is a diagram illustrating an example of a configuration of a semiconductor device according to Embodiment;

FIG. 8 is a diagram illustrating an example of a configuration of a semiconductor device according to Embodiment; and

FIG. 9 is a diagram conceptually illustrating an example of a configuration of a power conversion system including a power conversion apparatus according to Embodiment.

### DESCRIPTION OF THE PREFERRED EMBODIMENTS

Embodiments will be described below with reference to the accompanying drawings. In following Embodiments, although detailed features and the like are also illustrated for explaining the technique, they are mere examples, and not all of them are necessarily essential features to implement Embodiments.

It should be noted that the drawings are illustrated schematically, and for convenience of description, the configuration is to be omitted or the configuration is to be simplified as appropriate in the drawings. Also, the mutual relationship among sizes and positions in configurations and the like illustrated in separate drawings are not necessarily accurately drawn, and may be changed as appropriate. In addition, in the drawings such as plan views that are not cross-sectional views, hatching may be given to facilitate understanding of the contents of Embodiments.

In addition, in the following description, the same components are denoted by the same reference numerals, and the names and functions thereof are also similar. Accordingly, detailed descriptions thereof may be omitted to avoid redundancy.

Also, in the description to be made in the present specification, expressions that an X “is provided with”, “includes”, or “has” a component are not exclusive expressions that exclude the existence of other components unless otherwise specified.

Also, in the following description, even though ordinal numbers such as “first”, and “second” may be used, these terms are for promoting the understanding of the contents of Embodiments and are not limited to defining the order caused by such ordinal numbers.

Also, in the description to be made in the present specification, even though terms indicating specific positions or directions such as “upper”, “lower”, “left”, “right”, “side”, “bottom”, “front”, and “back” may be used, these terms are for promoting the understanding of the contents of Embodiments and are not related to the positions or directions at the time of implementation of Embodiments.

In addition, in the description to be made in the present specification, when the description such as “upper surface of an X” or “lower surface of an X” includes, in addition to the exact upper surface or the exact lower surface of the subject component, a state in which another component is formed on the upper surface or the lower surface of the subject component. In other words, for example, when stated as “B provided on the upper surface of A,” it does not preclude the presence of another component, “C,” intervening between A and B.

### Embodiment 1

Hereinafter, a semiconductor device according to Embodiment 1 will be described.

### Configuration of Semiconductor Device

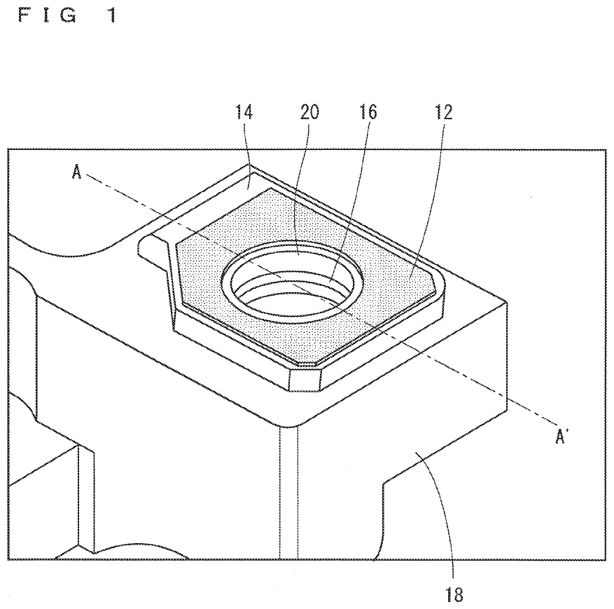

FIG. 1 is a diagram illustrating an example of a configuration of a semiconductor device according to Embodiment 1. As illustrated in FIG. 1, the semiconductor device has a structure in which a semiconductor chip is surrounded by a case 18, and a part of a main electrode 14 and a conductive material 12 provided (coated) on the upper surface of the main electrode 14 are exposed from the upper surface of the case 18. Also, an opening 20 is formed on the upper surface of the main electrode 14, and a nut 16 is formed inside the opening 20. Note that the conductive material 12 is provided so as to surround the opening 20 in plan view.

The conductive material 12 may be made of, for example, a phase change-thermal interface material (PC-TIM), and may have the characteristics of being solid at temperatures 45° C. or below and softening or liquefying at temperatures above 45° C. With such characteristics, the conductive material 12 is prevented from peeling off from the semiconductor device during transportation due to being solid at room temperature. Further, during operation of the semiconductor device, the conductive material 12 softens and has a favorable degree of adhesion to the bus bar, so that heat propagation or electrical conductivity can be improved. Also, the conductive material 12 may have a thermal conductivity of 3 [W/m·K] or more, for example, and may have high heat dissipation. With such characteristics, the heat generated inside the module can be efficiently propagated to a bus bar 36 due to a high thermal conductivity of the conductive material 12. Therefore, temperature rise of the main electrode 14 or inside the module can be suppressed.

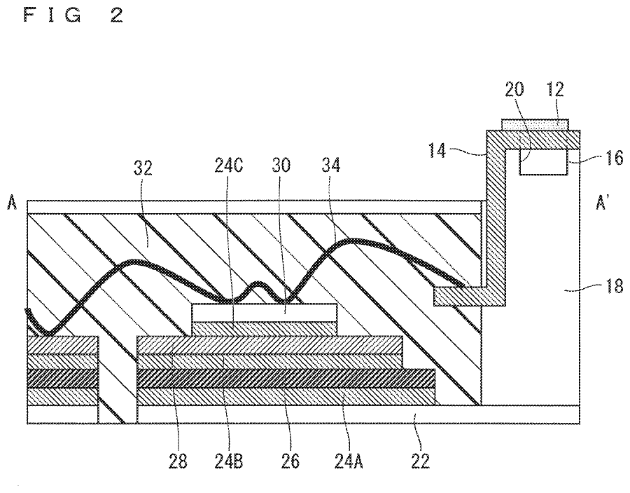

FIG. 2 is a cross-sectional view illustrating an example taken along line A-A′ in FIG. 1. As illustrated in FIG. 2, the semiconductor device includes a base plate 22, an insulating layer 26 provided on the upper surface of the base plate 22 via a bonding material 24A, a copper pattern 28 provided on a portion of the upper surface of the insulating layer 26 via a bonding material 24B, a semiconductor chip 30 provided on a portion of the upper surface of the copper pattern 28 via a bonding material 24C, a wire 34 provided in contact with the top surface of the semiconductor chip 30, the end of the main electrode 14 exposed from the side of the case 18 into the inside of the case 18, and the top surface of the copper pattern 28 (the upper surface of the copper pattern 28 that is separated from the copper pattern 28 on which the semiconductor chip 30 is provided), the case 18 provided on the upper surface of the base plate 22 and housing the insulating layer 26, the copper pattern 28, the semiconductor chip 30, and the wire 34, a main electrode 14 whose respective end portions are exposed from the external upper surface and inner surface of the case 18, the conductive material 12 provided (applied) on the upper surface of the main electrode 14 exposed to the outside of the case 18, a nut 16 provided inside the opening 20 of the main electrode 14, and a sealing resin 32 is filled inside the case 18, covering the base plate 22, the insulating layer 26, the copper pattern 28, the semiconductor chip 30, and the wire 34.

The semiconductor chip 30 may be an RC-IGBT in which a switching element and a freewheeling element are integrated into one chip, or a device using a wide bandgap semiconductor other than silicon, such as SiC or GaN. Here, wide bandgap semiconductors generally refer to semiconductors with a bandgap of approximately 2 eV or more, such as group 3 nitrides such as gallium nitride (GaN), group 2 oxides such as zinc oxide (ZnO), group 2 chalcogenides such as zinc selenide (ZnSe), diamond, and silicon carbide (SiC) etc. are known.

According to the semiconductor device according to Embodiment 1, the conductive material 12 is provided on the upper surface of the main electrode 14, thereby reducing the contact resistance or contact thermal resistance with the bus bar attached to the main electrode 14, enabling to suppress the temperature rise of the electrode or the inside of the module.

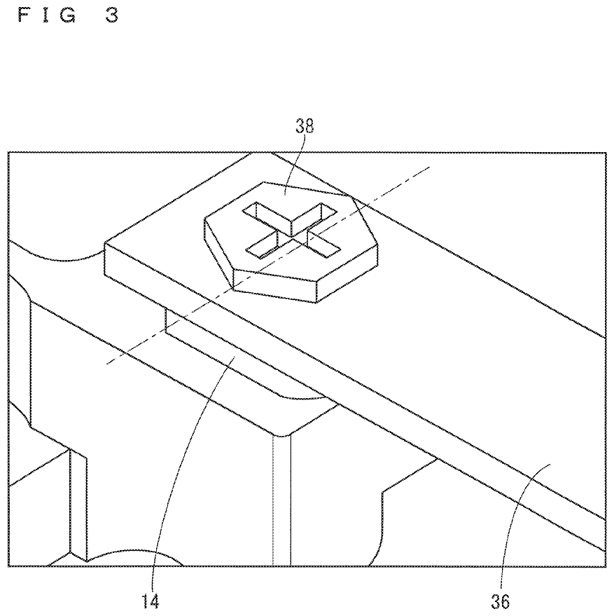

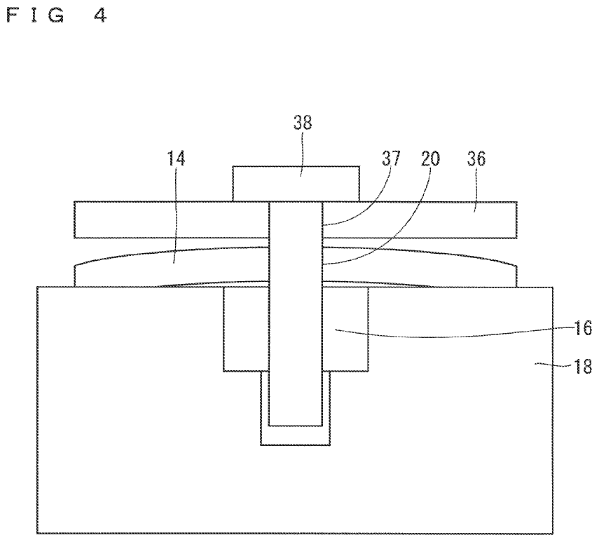

FIG. 3 is a diagram illustrating an example of a configuration when the bus bar is externally connected to the main electrode 14. And FIG. 4 is a cross-sectional view illustrating the example of the configuration when the bus bar is connected to the main electrode 14 illustrated in FIG. 3. As the example is illustrated in FIGS. 3 and 4, the bus bar 36 is attached to the upper surface of the main electrode 14 of the semiconductor device. Also, a screw 38 is inserted through an opening 37 provided in the bus bar 36 and the opening 20 provided in the main electrode 14, and the screw 38 is further screwed (fitted) into the nut 16, thereby fixing the screw 38 to the nut 16.

In this case, the main electrode 14 and the bus bar 36 are in contact with each other by the screw 38 fixed to the nut 16 as described above, however, when the front surface of the main electrode 14 has irregularities (including the main electrode 14 being warped) or when the front surface of the bus bar 36 has irregularities (including the bus bar 36 being warped), there is a region where the main electrode 14 and the bus bar 36 are not in contact with each other (i.e., the contact area reduces).

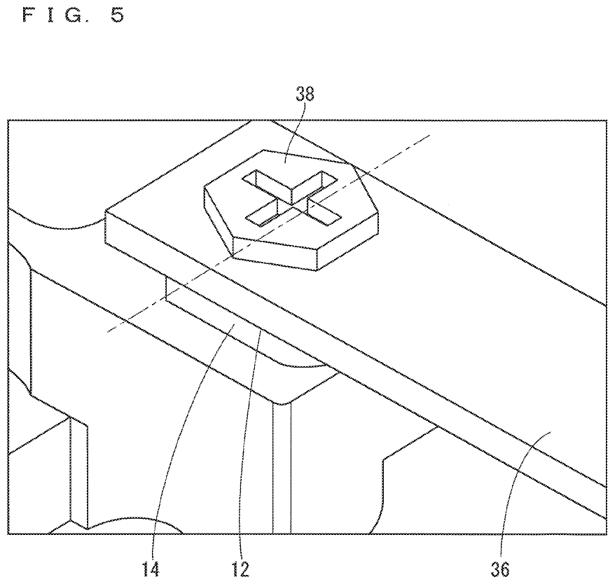

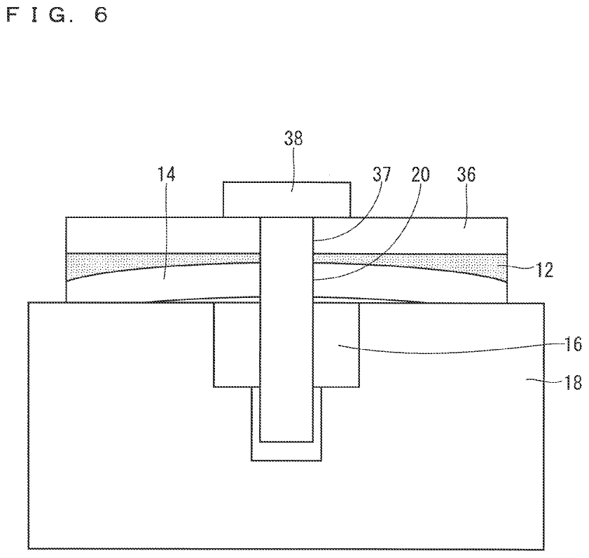

FIG. 5 is a diagram illustrating an example of a configuration when the bus bar is externally connected to the main electrode 14 of the semiconductor device according to Embodiment 1. And FIG. 6 is a cross-sectional view illustrating the example of the configuration when the bus bar is connected to the main electrode 14 illustrated in FIG. 5. As the example is illustrated in FIGS. 5 and 6, the bus bar 36 is attached to the upper surface of the main electrode 14 of the semiconductor device via the conductive material 12. Also, a screw 38 is inserted through an opening 37 provided in the bus bar 36 and the opening 20 provided in the main electrode 14, and the screw 38 is further screwed (fitted) into the nut 16, thereby fixing the screw 38 to the nut 16.

In this case, the main electrode 14 and the bus bar 36 are in contact with each other via the conductive material 12 by fixing the screw 38 to the nut 16 as described above. Therefore, even if the surface of the main electrode 14 has irregularities (including the main electrode 14 being warped) or the surface of the bus bar 36 has irregularities (including the bus bar 36 being warped), the main electrode 14 and the bus bar 36 are in indirectly contact with each other with the conductive material 12 filling into the region in which the main electrode 14 and the bus bar 36 are not in directly contact with each other. Therefore, the contact area between the main electrode 14 and the bus bar 36 does not reduce, and the contact resistance or contact thermal resistance between the main electrode 14 and the bus bar 36 can be reduced. By reducing the contact resistance at the location, heat generation at the contact portion can be suppressed. Further, by reducing the contact thermal resistance, the heat generated inside the module can be efficiently transferred to the bus bar 36, enabling to suppress the temperature rise of the electrode or the inside of the module.

### Embodiment 2

A semiconductor device according to Embodiment 2 will be described. In the following description, components similar to the components described in above Embodiment will be illustrated with the same reference numerals, and detailed description thereof will be omitted as appropriate.

### Configuration of Semiconductor Device

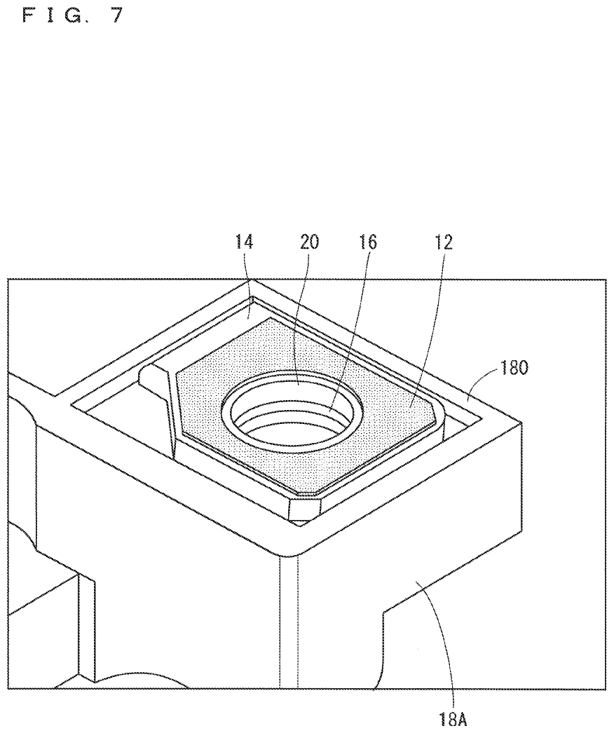

FIG. 7 is a diagram illustrating an example of a configuration of a semiconductor device according to Embodiment 2. As illustrated in FIG. 7, the semiconductor device has a structure in which a semiconductor chip is surrounded by a case 18A, and a part of a main electrode 14 and a conductive material 12 provided (coated) on the upper surface of the main electrode 14 are exposed from the upper surface of the case 18A. Also, an opening 20 is formed on the upper surface of the main electrode 14, and a nut 16 is formed inside the opening 20. Note that the conductive material 12 is provided so as to surround the opening 20 in plan view. Note that the internal configuration of the case 18A is similar to that illustrated in FIG. 2.

Further, a receiving portion 180 having a convex shape is formed on the upper surface of the case 18A where the main electrode 14 is provided so as to surround the main electrode 14 exposed from the case 18A in plan view. The receiving portion 180 is formed so as to go around, for example, an end portion of the upper surface of the case 18A. Note that the receiving portion 180 is not limited to being provided continuously so as to surround the main electrode 14 in plan view, but may be provided intermittently in the circumferential direction, for example.

By providing the receiving portion 180, when the bus bar is tightened to the main electrode 14 via the screw or when the conductive material 12 is melted, leakage of the conductive material 12, that is melted or other, from the upper surface of the main electrode 14 and running down of the conductive material 12, that is melted or other, to the case 18A (even further running down to the lower surface of the base plate 22 in FIG. 2) can be suppressed. Accordingly, the insulation performance between the main electrode 14 and the base plate 22 is maintained.

### Embodiment 3

A semiconductor device according to Embodiment 3 will be described. In the following description, components similar to the components described in above Embodiments will be illustrated with the same reference numerals, and detailed description thereof will be omitted as appropriate.

### Configuration of Semiconductor Device

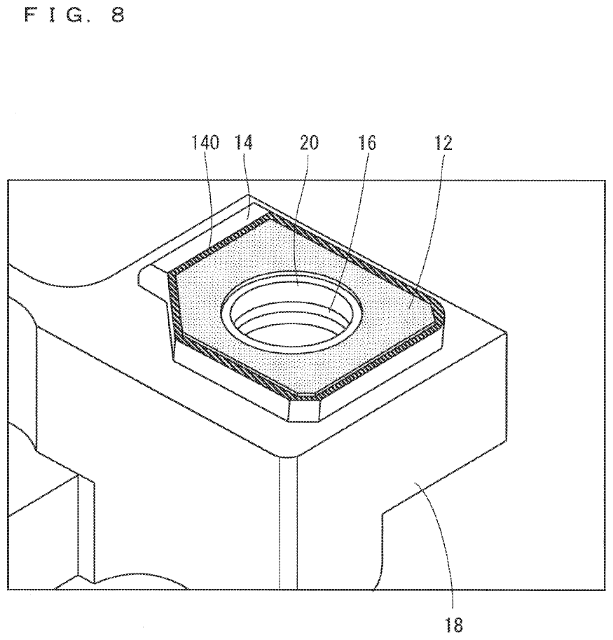

FIG. 8 is a diagram illustrating an example of a configuration of a semiconductor device according to Embodiment 3. As illustrated in FIG. 8, the semiconductor device has a structure in which a semiconductor chip is surrounded by a case 18, and a part of a main electrode 14 and a conductive material 12 provided (coated) on the upper surface of the main electrode 14 are exposed from the upper surface of the case 18. Also, an opening 20 is formed on the upper surface of the main electrode 14, and a nut 16 is formed inside the opening 20. Note that the conductive material 12 is provided so as to surround the opening 20 in plan view. Note that the internal configuration of the case 18 is similar to that illustrated in FIG. 2.

Further, a resist 140 is provided on the upper surface of the main electrode 14 exposed from the case 18 so as to surround the conductive material 12 in plan view. The resist 140 is formed so as to go around, for example, an end portion of the upper surface of the main electrode 14. Note that the resist 140 is not limited to being provided continuously so as to surround the conductive material 12 in plan view, but may be provided intermittently in the circumferential direction, for example.

By providing the resist 140, when the bus bar is tightened to the main electrode 14 via the screw or when the conductive material 12 is melted, leakage of the conductive material 12, that is melted or other, from the upper surface of the main electrode 14 and running down of the conductive material 12, that is melted or other, to the case 18 (even further running down to the lower surface of the base plate 22 in FIG. 2) can be suppressed. Accordingly, the insulation performance between the main electrode 14 and the base plate 22 is maintained.

Note that the resist 140 is applicable to the configuration in which the receiving portion 180 illustrated in FIG. 7 is provided.

### Embodiment 4

A power conversion apparatus and a method of manufacturing the power conversion apparatus according to Embodiment 4 will be described. In the following description, components similar to the components described in above Embodiments will be illustrated with the same reference numerals, and detailed description thereof will be omitted as appropriate.

### Configuration of Power Conversion Apparatus

In Embodiment 4, the semiconductor device according to Embodiments described above is applied to a power conversion apparatus. The power conversion apparatus to be applied is not limited to specific applications; however, the following describes its application in the case of a three-phase inverter.

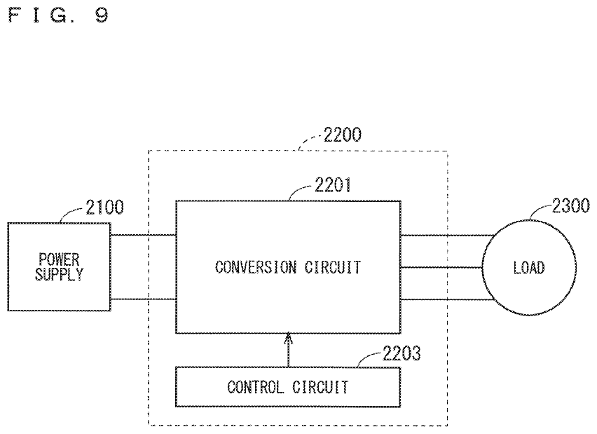

FIG. 9 is a diagram conceptually illustrating an example of a configuration of a power conversion system including the power conversion apparatus according to Embodiment 4.

As an example illustrated in FIG. 9, the power conversion system includes a power supply 2100, a power conversion apparatus 2200, and a load 2300. The power supply 2100 is a DC power supply and supplies DC power to the power conversion apparatus 2200. The power supply 2100 can be configured with various elements, such as a DC system, a solar battery, or a storage battery. Also, the power supply 2100 can be configured with a rectifier circuit, an AC-DC converter or the like connected to an AC system. Also, the power supply 2100 may be configured by a DC/DC converter that converts DC power output from a DC system into predetermined power.

The power conversion apparatus 2200 is a three-phase inverter connected between the power supply 2100 and the load 2300. The power conversion apparatus 2200 converts DC power supplied from the power supply 2100 into AC power, and further supplies the AC power to the load 2300.

As illustrated in the example in FIG. 9, the power conversion apparatus 2200 includes a conversion circuit 2201 that converts DC power into AC power and outputs the AC power, and a control circuit 2203 that outputs a control signal for controlling the conversion circuit 2201 to the conversion circuit 2201.

The load 2300 is a three-phase electric motor driven by AC power supplied from the power conversion apparatus 2200. Note that the load 2300 is not limited to a specific application, and is an electric motor installed in various electrical devices, and is used, for example, as an electric motor for a hybrid vehicle, an electric vehicle, a railway vehicle, an elevator, or an air conditioner.

Hereinafter, the details of the power conversion apparatus 2200 will be described below. The conversion circuit 2201 includes a switching element and a free wheel diode (not illustrated). Then, the switching element performs a switching operation to convert the DC power supplied from the power supply 2100 into AC power, which is further supplied to the load 2300.

While there are various specific circuit configurations of the conversion circuit 2201, the conversion circuit 2201 according to Embodiment 4 is a two-level, three-phase full bridge circuit, and includes six switching elements and six freewheeling diodes each connected antiparallel to the respective switching element.

The semiconductor device in any of Embodiments described above is applied to at least one of each switching element and each freewheeling diode in the conversion circuit 2201. The six switching elements are connected in series in pairs to form upper and lower arms, with each upper and lower arm constituting each phase (U-phase, V-phase, W-phase) of the full bridge circuit. The output terminal of each of the upper and lower arms, that is, the three output terminals of the conversion circuit 2201, are connected to the load 2300.

Further, the conversion circuit 2201 includes a drive circuit (not illustrated) that drives each switching element, and the configuration to be adopted may include the drive circuit built in a semiconductor device that is a semiconductor module, or the drive circuit provided separately from the module. The drive circuit generates a drive signal for driving the switching elements of the conversion circuit 2201, and further supplies the drive signal to control electrodes of the switching elements of the conversion circuit 2201. Specifically, in response to a control signal from the control circuit 2203, which will be described later, a drive signal that turns the switching element on and a drive signal that turns the switching element off are output to the control electrode of each switching element.

When keeping the switching element in the on state, the drive signal is a voltage signal (on signal) that is equal to or greater than a threshold voltage of the switching element, and when keeping the switching element in the off state, the drive signal is a voltage signal (off signal) that is equal to or less than the threshold voltage of the switching element.

The control circuit 2203 controls switching elements of the conversion circuit 2201 so that desired power is supplied to the load 2300. Specifically, based on the power to be supplied to the load 2300, the time (on time) during which each switching element of the conversion circuit 2201 should be in the on state is calculated. For example, the conversion circuit 2201 can be controlled by PWM control that modulates the on time of the switching element according to the voltage to be output.

Then, the control circuit 2203 outputs a control command (that is, a control signal) to the drive circuit so that an on signal is output to the switching element that should be in the on state and an off signal is output to the switching element that should be in the off state, at each time. The drive circuit outputs an on signal or an off signal as a drive signal to the control electrode of each switching element in response to the control signal.

In the power conversion apparatus 2200 according to Embodiment 4, the semiconductor device according to any of Embodiments described above is applied as the switching element of the conversion circuit 2201; therefore, the on-resistance after passing through the electrical cycle can be stabilized.

Note that in Embodiment 4, although an example has been described in which the semiconductor device in any of Embodiments described above is applied to a two-level three-phase inverter, the application example is not limited thereto, and the semiconductor device in any of Embodiments described above can be applied to various power conversion apparatuses.

Further, in Embodiment 4, although the two-level power conversion device has been described, the semiconductor device in any of Embodiments described above may be applied to a three-level or multi-level power conversion apparatus. Further, when power is supplied to a single-phase load, the semiconductor device in any of Embodiments described above may be applied to a single-phase inverter.

Further, when power is supplied to a DC load or the like, the semiconductor device in any of Embodiments described above can be applied to a DC-DC converter or an AC-DC converter.

Further, the power conversion apparatus to which the semiconductor device in any of Embodiments described above is applied is not limited to the case where the load described above is an electric motor, but is used, for example, as a power supply device for an electrical discharge machine, a laser processing machine, an induction heating cooker, or a non-contact power supply system. Further, a power conversion apparatus to which the semiconductor device in any of Embodiments described above is applied can also be used as a power conditioner in a solar power generation system, a power storage system, or the like.

### Method of Manufacturing Power Conversion Apparatus

A method of manufacturing the power conversion apparatus according to Embodiment 4 will be described.

First, the semiconductor device is manufactured using the manufacturing method described in Embodiments described above. Then, the conversion circuit 2201 having the semiconductor device is provided as a configuration of a power conversion apparatus. The conversion circuit 2201 is a circuit for converting and outputting power to be input.

The control circuit 2203 is provided as a configuration of the power conversion apparatus. The control circuit 2203 is a circuit for outputting a control signal for controlling the conversion circuit 2201 to the conversion circuit 2201.

The semiconductor switching element used in Embodiments described above is not limited to a switching element made of a silicon (Si) semiconductor, and for example, a semiconductor switching element may be made of a non-Si semiconductor material having a wider bandgap than that of a Si semiconductor may be adoptable.

Examples of wide bandgap semiconductors that are non-Si semiconductor materials include silicon carbide, gallium nitride-based materials, diamond, and the like.

The switching elements, made of wide bandgap semiconductors, can be used even in high voltage regions where there is some difficulty with unipolar operation with Si semiconductors, and can significantly reduce switching losses that occur during switching operations. This allows the great reduction in power loss.

Further, the switching elements made of wide bandgap semiconductors have low power loss and high heat resistance. Therefore, when configuring a power module including a cooling portion, reduction in size of the radiation fins of the heat sink is enabled, thereby implementing further reduction in size of the semiconductor module.

Further, the switching elements made of wide bandgap semiconductors are suitable for high frequency switching operations. Therefore, when applied to converter circuits that require high frequency, due to the increased switching frequency, downsizing reactors, capacitors, etc. connected to the converter circuit is enabled.

Therefore, similar effects can be obtained even when the semiconductor switching elements in Embodiments described above are made up with switching elements made of a wide gap semiconductor such as silicon carbide.

### Effects Produced by Plurality of Embodiments Described Above

Next, examples of effects produced by the plurality of Embodiments described above will be described. In the following description, although the effects are described based on the specific configuration described in the plurality of Embodiments described above, to the extent that the same effects are produced, such a specific configuration may be replaced with another specific configuration described in the present specification. In other words, for convenience, only one of the specific configurations that are associated may be described below as a representative, however, the specific configuration described as a representative may be replaced with another specific configuration to which it is associated.

Further, the replacement may be made across the plurality of Embodiments. That is, the respective configurations illustrated as the examples in different Embodiments may be combined to produce similar effects.

According to Embodiments described above, the semiconductor device includes the semiconductor chip 30, the case 18 (or the case 18A) that houses the semiconductor chip 30 therein, the main electrode 14, and the conductive material 12. The main electrode 14 is electrically connected to the semiconductor chip 30 via wire 34. Further, a portion of the main electrode 14 is exposed to the outside from the case 18 (or the case 18A). The conductive material 12 is applied to the front surface of the main electrode 14 exposed from the case 18 (or the case 18A). The front surface of the main electrode 14 is the surface connected to the bus bar 36.

According to such a configuration, the main electrode 14 and the bus bar 36 are in contact with each other via the conductive material 12. Therefore, even if the surface of the main electrode 14 has irregularities (including the main electrode 14 being warped) or the surface of the bus bar 36 has irregularities (including the bus bar 36 being warped), the main electrode 14 and the bus bar 36 are in indirectly contact with each other with the conductive material 12 filling into the region in which the main electrode 14 and the bus bar 36 are not in directly contact with each other. Therefore, the contact area between the main electrode 14 and the bus bar 36 does not reduce, and the contact resistance or contact thermal resistance between the main electrode 14 and the bus bar 36 can be reduced.

In addition, in the case where other configurations illustrated in the present specification are appropriately added to the above configuration, that is, when other configurations in the present specification that are not mentioned as the above configurations are appropriately added, even in such a case, the same effect can be produced.

Further, according to Embodiment described above, the receiving portion 180, which has a convex shape, surrounding the main electrode 14 exposed from the case 18A in plan view is formed on the front surface of the case 18A. According to such a configuration, leakage down of the conductive material 12, that is melted or other, from the upper surface of the main electrode 14 and running down of the conductive material 12, that is melted or other, to the case 18A (even further running down to the lower surface of the base plate 22 in FIG. 2) can be suppressed. Accordingly, the insulation performance between the main electrode 14 and the base plate 22 is maintained.

Furthermore, according to Embodiment described above, the semiconductor device includes the resist 140 that surrounds the conductive material 12 in plan view and is provided on the front surface of the main electrode 14 exposed from the case 18 (or the case 18A). According to such a configuration, leakage of the conductive material 12, that is melted or other, from the upper surface of the main electrode 14 and running down of the conductive material 12, that is melted or other, to the case 18A (even further running down to the lower surface of the base plate 22 in FIG. 2) can be suppressed. Accordingly, the insulation performance between the main electrode 14 and the base plate 22 is maintained.

Further, according to Embodiment described above, the conductive material 12 has a thermal conductivity of 3 [W/m·K] or more. According to such a configuration, the heat generated inside the module can be efficiently propagated to the bus bar 36 due to a high thermal conductivity of the conductive material 12. Therefore, temperature rise inside the main electrode 14 or the module can be suppressed.

Further, according to Embodiment described above, the conductive material 12 has the characteristics of being in a solid state at temperatures 45° C. or below and softening or liquefying at temperatures above 45° C. According to such a configuration, the conductive material 12 is prevented from peeling off from the semiconductor device during transportation due to being solid at room temperature. Further, during operation of the semiconductor device, the conductive material 12 softens and has a favorable degree of adhesion to the bus bar 36, so that heat propagation or electrical conductivity can be improved.

Further, according to Embodiment described above, the semiconductor chip 30 is made of a wide bandgap semiconductor. According to such a configuration, reduction in size of the module is enabled while improving the accuracy of overcurrent protection.

Further, according to Embodiment described above, the power conversion apparatus includes the above semiconductor device, and the conversion circuit 2201 that converts and outputs input power, and the control circuit 2203 that outputs a control signal for controlling the conversion circuit 2201 to the conversion circuit 2201. According to such a configuration, the contact area between the main electrode 14 and the bus bar 36 does not reduce, and the contact resistance or contact thermal resistance between the main electrode 14 and the bus bar 36 can be reduced.

### Modification of Plurality of Embodiments Described Above

Although in the plurality of Embodiments described above, the qualities of materials of, materials of, dimensions of, shapes of, relative arrangement relationships, or conditions of implementation of each component may also be described, they are illustrative in all aspects and are not limitative.

Accordingly, it is understood that numerous other modifications variations, and equivalents can be devised without departing from the scope of the invention. For example, a case where modifying at least one component, a case where adding or omitting components, and further, a case where extracting at least one component in at least one Embodiment and combining it with a component of another Embodiment are included.

Further, in at least one above-described Embodiment, when a material name or the like is described without being specified, the material contains other additives, for example, an alloy or the like, so far as consistent with Embodiments.

Further, “one or more” components may be included when described that “one” component is provided in Embodiments described above, so far as consistent with Embodiments.

Furthermore, each component in Embodiments described above is a conceptual unit, and within the scope of the technology disclosed in the present specification, a case where one component is composed of a plurality of structures, a case where one component corresponds to a part of a structure, and further, a case where a plurality of components are provided in one structure are included.

Further, each component in Embodiments described above includes a structure having another structure or shape as long as the same function is exhibited.

Also, the descriptions in the present specification are referred for the every object related to the technique, and none of them are regarded as conventional techniques.

Hereinafter, the aspects of the present disclosure will be collectively described as Appendices.

### Appendix 1

A semiconductor device comprising:
a semiconductor chip;
a case that houses the semiconductor chip therein;
a main electrode electrically connected to the semiconductor chip via a wire and partially exposed to outside from the case; and
a conductive material applied to a front surface of the main electrode exposed from the case, wherein
the front surface of the main electrode is the surface connected to a bus bar.

### Appendix 2

The semiconductor device according to Appendix 1, wherein
a receiving portion having a convex shape that surrounds the main electrode exposed from the case in plan view is formed on a front surface of the case.

### Appendix 3

The semiconductor device according to Appendix 1 or 2, further comprising
a resist surrounding the conductive material in plan view and provided on the front surface of the main electrode exposed from the case.

### Appendix 4

The semiconductor device according to any one of Appendices 1 to 3, wherein
the conductive material has a thermal conductivity of 3 [W/m·K] or more.

### Appendix 5

The semiconductor device according to any one of Appendices 1 to 4, wherein
the conductive material has characteristics of being in a solid state at temperatures 45° C. or below and softening or liquefying at temperatures above 45° C.

### Appendix 6

The semiconductor device according to any one of Appendices 1 to 5, wherein
the semiconductor chip is made of a wide bandgap semiconductor.

### Appendix 7

A power conversion apparatus comprising:
a conversion circuit including at least one semiconductor device according to any one of Appendices 1 to 6, and configured to convert and output input power; and
a control circuit configured to output a control signal for controlling the conversion circuit to the conversion circuit.

While the invention has been illustrated and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor chip;
a case that houses the semiconductor chip therein;
a main electrode electrically connected to the semiconductor chip via a wire and partially exposed to outside from the case; and
a conductive material applied to a front surface of the main electrode exposed from the case, wherein
the front surface of the main electrode is the surface connected to a bus bar.

2. The semiconductor device according to claim 1, wherein
a receiving portion having a convex shape that surrounds the main electrode exposed from the case in plan view is formed on a front surface of the case.

3. The semiconductor device according to claim 1, further comprising
a resist surrounding the conductive material in plan view and provided on the front surface of the main electrode exposed from the case.

4. The semiconductor device according to claim 1, wherein
the conductive material has a thermal conductivity of 3 [W/m·K] or more.

5. The semiconductor device according to claim 1, wherein
the conductive material has characteristics of being in a solid state at temperatures 45° C. or below and softening or liquefying at temperatures above 45° C.

6. The semiconductor device according to claim 1, wherein
the semiconductor chip is made of a wide bandgap semiconductor.

7. A power conversion apparatus comprising:
a conversion circuit including at least one semiconductor device according to claim 1, and configured to convert and output input power, and
a control circuit configured to output a control signal for controlling the conversion circuit to the conversion circuit.
